(19) United States
(12) Patent Application Publication
(10) Pub. No.: US 2017/0073830 A1
(43) Pub. Date: Mar. 16, 2017

(54) ELECTROPLATING APPARATUS, ELECTROPLATING METHOD, AND METHOD OF MANUFACTURING SEMICONDUCTOR DEVICE

(71) Applicant: Kabushiki Kaisha Toshiba, Minato-ku (JP)

(72) Inventor: Kazuhito HIGUCHI, Yokohama (JP)

(73) Assignee: Kabushiki Kaisha Toshiba, Minato-ku (JP)

(21) Appl. No.: 15/258,309

(22) Filed: Sep. 7, 2016

(30) Foreign Application Priority Data
Sep. 10, 2015 (JP) 2015-178435

(51) Int. Cl. C25D 7/12; H01L 21/288; C25D 5/02; C25D 3/38; C25D 17/02

(52) U.S. Cl. CPC C25D 7/123; C25D 3/38; C25D 17/02; C25D 5/02; H01L 21/2885

(57) ABSTRACT

According to an embodiment, an anode portion and a cathode portion are arranged in a reaction tank so as to opposite to each other with a distance provided. A plating solution which contains at least metal ions for plating, an electrolyte and a surfactant is provided in the reaction tank. A pattern of a metal plating film is formed on a surface of the cathode portion by setting the cathode portion at a negative electric potential with respect to an electric potential of the anode portion. A distance between the anode portion and a surface of a pattern of the metal plating film to be formed on the surface of the cathode portion is set to be smaller than a half value width of a cross-section of a portion of the pattern of the metal plating film having a minimum width.

### CROSS-REFERENCE TO RELATED APPLICATION

The application is based upon and claims the benefit of priority from the prior Japanese Patent Application No. 2015-178435, filed on Sep. 10, 2015, the entire contents of which are incorporated herein by reference.

### FIELD

Embodiments described herein relate generally to an electroplating apparatus, an electroplating method and a method of manufacturing a semiconductor device

### BACKGROUND

In recent years, development and popularization of information processing technologies progress size reduction, thickness reduction and high performance of electronic apparatuses. With such a progress, sizes of semiconductor packages tend to decrease. Particularly, a semiconductor package having several pins to about 100 pins which is used for a mobile terminal etc. changes from a small out-line package (SOP) and a quad flat package (QFP), which are conventional, to a small out-line non-lead package (SON) and a quad flat non-lead package (QFN) which are smaller packages of a non-lead type, and further changes in form to a wafer-level chip scale package (WCSP) in recent years.

In a general package of WCSP, solder balls are formed in a lattice pattern on a lower surface of the package. The solder balls are provided on electrodes of a substrate and are connected to the electrodes.

A manufacturing process of packages such as SOP, QFP, SON, QFN includes steps of mounting an individualized semiconductor chip after dicing on a lead frame, connecting using wire bonding, of molding using a sealing resin, separating leads and externally electroplating the leads.

On the other hand, in a manufacturing process of a package of WCSP, a semiconductor wafer is only diced into individual pieces after solder balls are mounted on a surface of the semiconductor wafer in a stage before the semiconductor wafer is diced into semiconductor chips, and the productivity is extremely high accordingly.

In a package of WCSP, since an arrangement of electrode pads of a chip is converted into an arrangement of solder balls, it is necessary to form rewiring by a semi-additive method using Cu electroplating. The semi-additive method includes five steps of forming a seed layer serving as a cathode at a time of electroplating, forming a resist layer in which a rewiring pattern is formed, Cu plating by electroplating, removing the resist layer and etching the seed layer.

These steps are positioned in a middle of a back-end of line (BEOL) as a previous process and a post-process with respect to process and size, and thus are called as intermediate steps. Since these steps use a wafer process, an apparatus close to an apparatus which is used in BEOL is used for mass-production.

More specifically, laminated thin films of Ti and Cu may be used to form a seed layer. In order to form the laminated thin films, a sputtering apparatus which forms a metal thin film on a wafer is used. In addition, In order to form a resist layer, a coater/developer which performs resist coating, baking, development, cleaning and drying automatically and a stepper exposure apparatus are used.

An electroplating apparatus needs to apply current to a seed layer provided on a surface of a wafer. Accordingly, a single wafer type apparatus is used as the electroplating apparatus in order to obtain contact points for conduction by disposing each wafer in a holder. In a general electroplating apparatus, in order to improve the film thickness uniformity of an electroplating film, a distance between a wafer on which a seed layer serving as a cathode is formed and an anode is set to be as large as possible. Such a distance is at least 1 mm or more and, generally is 10 mm or more. In addition, in a manufacturing process of a package of WCSP, three steps of eliminating oxides provided on the surface of the seed layer, Cu electroplating and a cleaning/drying step are necessary. Accordingly, in order to prevent mutual contamination between the steps, an apparatus including separate processing tanks for the respective steps and an automatic conveying device for conveying between the tanks is used.

Since, after the steps, wafer is only immersed in a removing liquid or an etching liquid in an apparatus for removing a resist layer and an etching apparatus for etching a seed layer, apparatuses of a batch type which can process a plurality of wafers simultaneously may be used in addition to apparatuses of a signal wafer type. In such a case, apparatuses which have separate washing tanks in addition to processing tanks respectively and an automatic conveying device for conveying between the tanks may be used, in order to prevent mutual contamination between the steps similarly to plating apparatus.

By a series of processes using these apparatuses, a wiring having a minimum line width of 10 μm or less or a wiring having an aspect ratio of 0.5 or more can be formed. The aspect ratio is a ratio of a wiring height to a wiring width. In addition, Cu having low resistivity can be used as an electroplating material, and both a high wiring density and a low electric resistance can be obtained.

A series of these apparatuses have a high processing capacity of several 1000 wafers/month or more, but each apparatus is much more expensive than ordinary post-processing apparatuses such as a wire binding apparatus, a die bonding apparatus etc. and requires a large installation space. Thus, it is difficult to apply the apparatuses to a product of many kinds in small quantities, and the apparatuses is difficult to operate to respond to a change in amount of production in a flexible manner.

In order to manufacture a package of WCSP, a large floor area in which production apparatuses of a large scale can be installed is necessary, and an initial investment of a high cost is required. Thus, as described above, it is difficult to apply WCSP to products of many kinds in small quantities despite these problem. Particularly, in a series of steps, the steps of resist forming, exposure, development and removing respectively relating to a resist occupies a half or more of the whole steps, and these steps employ indirect processes in which materials to be used do not to remain as a constituent material of final products. Techniques of simplifying processes relating to a resist are developed for productivity improvement and low cost.

For example, a technique of ejecting a metal nano paste using an ink jet method and forming a metal wiring pattern on a substrate without using a resist is known. According to the technique, a wiring having a thickness of 2 μm, a minimum line width of about 30 μm and a pitch of about 60 μm can be formed by directly drawing the wiring on a base member using a material such as silver or cooper.

However, in the method, since the nano paste having low viscosity is used and thus a strong influence of an interaction with a surface of the base member occurs, it is difficult to form a stable and fine pattern. The thickness of the wiring is restricted and it is difficult to form a wiring pattern the aspect ratio of which exceeds 0.5. In addition, the wiring is obtained by sintering the nano paste, and thus the wiring has properties different from a pure bulk metal and inferior as compared with those of a bulk material in electric resistance, elongation percentage, tensile strength etc. There is a problem that the electrical performance and the reliability are lower than those of a wiring formed using a semi-additive method according to conventional electroplating.

### BRIEF DESCRIPTION OF THE DRAWINGS

FIG. 1 is a schematic diagram which illustrates a configuration of an electroplating apparatus according to a first embodiment;

FIG. 2 is a schematic diagram which illustrates a configuration of a part of the electroplating apparatus;

FIG. 3 is a diagram which illustrates a current distribution at a cathode portion according to an electroplating method using the electroplating apparatus;

FIG. 4 is a diagram which illustrates changes in current density and inter-electrode distance with respect to time according to the electroplating method;

FIG. 5 is a diagram which illustrates a sectional shape of a copper wiring formed using the electroplating method;

FIG. 6 is a cross-sectional view which illustrates an example of a semiconductor device to be manufactured using the electroplating method;

FIG. 7 is a schematic diagram which illustrates a configuration of a part of an electroplating apparatus according to a second embodiment;

FIG. 8 is a schematic diagram which illustrates a configuration of a part of an electroplating apparatus according to a third embodiment;

FIG. 9 is a diagram which illustrates a configuration of an anode portion of the electroplating apparatus according to the third embodiment;

FIG. 10 is a schematic diagram which illustrates an example of a method of manufacturing a wiring board or a semiconductor device by an electroplating method using the apparatus according to the third embodiment;

FIG. 11 is a schematic diagram which illustrates another example of a method of manufacturing a wiring board or a semiconductor device by the electroplating method using the apparatus according to the third embodiment; and

FIG. 12 is a schematic diagram which illustrates a relation between a current density and an inter-electrode distance according to another electroplating method.

### DETAILED DESCRIPTION

According to an electroplating method of an embodiment, an anode portion having a pattern and a cathode portion are arranged in a reaction tank so as to opposite to each other with a distance provided. A plating solution which contains at least metal ions for electroplating, an electrolyte and a surfactant is provided in the reaction tank. A pattern of a metal plating film is formed on a surface of the cathode portion by setting the cathode portion at a negative electric potential with respect to an electric potential of the anode portion. A distance between the anode portion and a surface of a pattern of the metal plating film to be formed on the surface of the cathode portion is set to be smaller than a half value width of a cross-section of a portion of the pattern of the metal plating film having a minimum width, by controlling a distance between the anode portion and the cathode portion.

Hereinafter, further embodiments will be described with reference to the drawings. In the drawings, the same reference numerals denote the same or similar portions respectively.

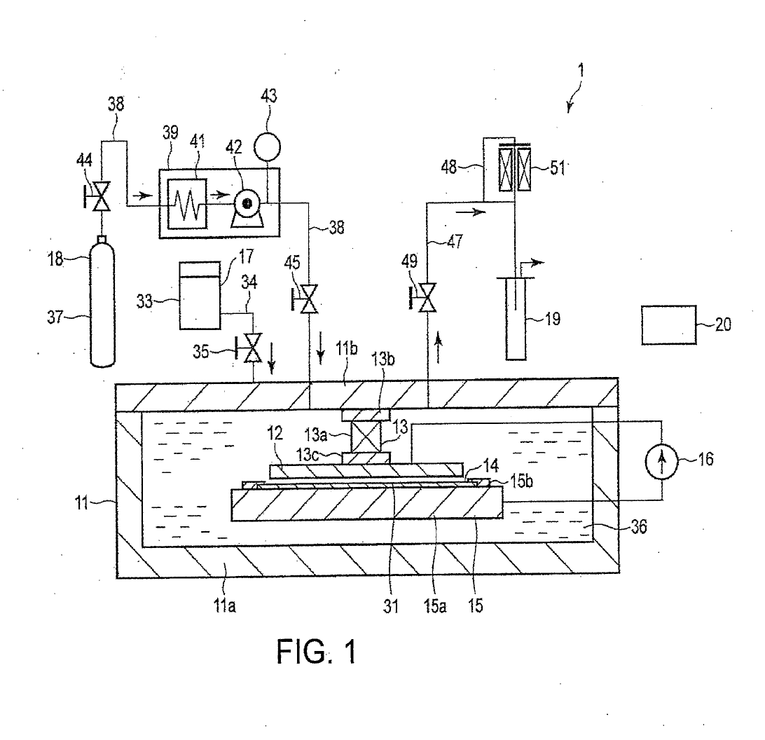

With reference to FIGS. 1 to 6, an electroplating apparatus according to a first embodiment and a method of manufacturing a semiconductor device or a wiring board according to an electroplating method using the electroplating apparatus will be described. In each figure, configurations may be appropriately enlarged, reduced or omitted for description convenience. FIG. 1 is a schematic diagram which illustrates a configuration of the electroplating apparatus according to the first embodiment.

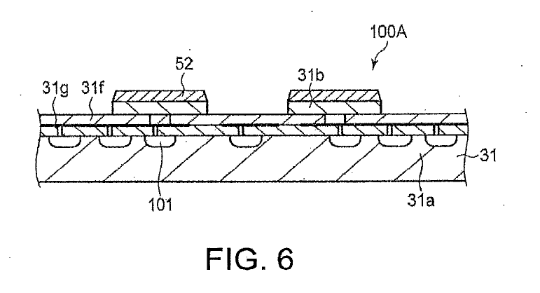

The first embodiment shows a method of manufacturing a semiconductor device as an example of an electroplating method. The method includes mixing supercritical CO₂ with a plating solution, immersing a base member in the plating solution, and forming a copper wiring as a plating film on the base member. The semiconductor device to be manufactured is illustrated in FIG. 6.

The semiconductor device 100A is manufactured as a package of a WCSP etc. by forming semiconductor devices 101 on a base member 31, for example, a silicon substrate and forming a plating film 52 on the base member 31. The semiconductor device 100A includes a wiring 31g connected to the semiconductor device 101, an insulating layer 31f, and a plating film 52 connected to the wiring 31g through a seed layer 31b.

As illustrated in FIG. 1, the electroplating apparatus 1 according to the embodiment includes a reaction tank 11, an anode portion 12, an anode supporting portion 13, a cathode portion 14, a cathode supporting portion 15, a DC constant current source 16 to be used for energization, a supercritical fluid supplying unit 18, a plating solution supplying unit 17, a treatment container 1, and a control unit 20 for controlling these portions and units. The reaction tank 11 houses a plating solution 36.

The anode portion 12 is arranged inside the reaction tank 11. The anode supporting portion 13 supports the anode portion 12. The cathode portion 14 is arranged to oppose the anode portion 12 inside the reaction tank 11. The cathode supporting portion 15 supports the cathode portion 14. The supercritical fluid supplying unit 18 is connected to the supply side of the reaction tank 11 through a fluid supplying pipe 38. The plating solution supplying unit 17 is connected to the supply side of the reaction tank 11 through a liquid supplying pipe 34. The treatment container 19 is connected to a discharge side of the reaction tank 11 through a discharge pipe 47.

The reaction tank 11 is configured by, for example, a pressure container made of stainless steel whose inner wall is coated with a fluorine-based resin and an upper side is open. The reaction tank 11 includes a case body 11a of a square casing shape having an opening at an upper portion, and a lid body 11b provided in the case body 11a to have the opening open or closed. In the reaction tank 11, a plating solution 36 and CO₂ which is in a supercritical state are housed. The reaction tank 11 includes an inner space in which the anode portion 12 and the cathode portion 14 oppose each other. The reaction tank 11 is connected to the plating solution supplying unit 17 and the supercritical fluid supplying unit 18 respectively through the fluid supplying pipe 38 and the liquid supplying pipe 34 and is connected to the treatment container 19 through the discharge pipe 47.

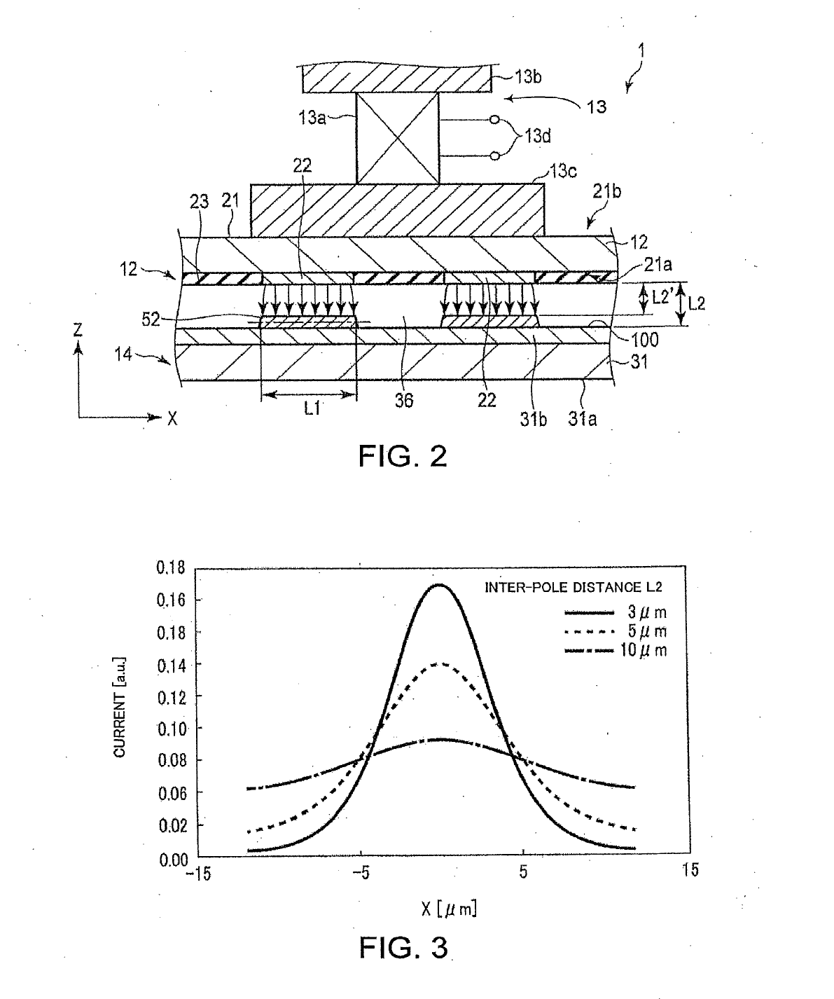

FIG. 2 is a partly-enlarged view of the electroplating apparatus illustrated in FIG. 1. As illustrated in FIG. 2, the anode portion 12 includes a base 21 having conductivity, an electrode surface portion 22 which is formed on a surface of the base 21 on a side of the cathode portion 14, and an insulating film 23.

The base 21 is formed using a pure copper plate, for example, has an XY plane, and includes a first surface 21a and a second surface 21b. The base 21 is formed in a circular plate shape having a diameter of 220 mm, for example. On the first surface 21a of the base 21, the insulating film 23 and the electrode surface portion 22 are formed. The second surface 21b of the base 21 is bonded to the anode supporting portion 13 and is attached to be movable in a Z-axis direction. The base 21 i.e. the anode portion 12 is connected to a positive electrode of the DC constant current source 16 through a connection lead, as illustrated in FIG. 1.

The electrode surface portion 22 as an anode is configured by a film of Ti/Pt, for example, and is formed in a predetermined pattern shape corresponding to a pattern shape of the plating film 52. In the embodiment, the center line of the pattern of the electrode surface portion 22 opposes and extends along the center line of the pattern of the plating film 52 formed on the base member 31. The width of the pattern of the electrode surface portion 22 is adjusted to the width of the pattern of the plating film 52. For example, in a case where a wiring pattern having a width of about 20 μm, a height i.e. a film thickness of about 10 μm, a half value width of 10 μm with respect to a maximum height of the pattern cross section and a pitch of 40 μm is required to be formed, the electrode surface portion 22 is formed in a pattern shape having a minimum width of the pattern width of 10 μm, an interval of 30 μm, and a pitch of 40 μm. The electrode surface portion 22 is connected to an anode of the DC constant current source 16 through the base 21.

The insulating film 23 is formed of an inorganic film of SiO₂ or SiN, or an organic film formed of polyimide, epoxy etc. On the first surface 21a of the base 21, the insulating film 23 is formed at an area adjacent to the electrode surface portion 22 on the periphery of the electrode surface portion 22 i.e. an area in which the electrode surface portion 22 is not formed.

On the first surface 21a of the base 21, the electrode surface portion 22 is formed in a pattern shape in a predetermined area. The insulating film 23 is formed at the other area. The surface of the electrode surface portion 22 and the insulating film 23 constitute approximately the same surface.

The anode supporting portion 13 is an adjustment device configured to adjust an inter-electrode distance L2 by adjusting the position of the anode portion 12 in the Z direction. The anode supporting portion 13 includes a piezoelectric portion 13a, a first support plate 13b, and a second support plate 13c. The length of the piezoelectric portion 13a in the Z direction can be changed. The first support plate 13b is provided on one side of the piezoelectric portion 13a and has a bonding surface bonded to the lid body 11b illustrated in FIG. 1. The second support plate 13c is provided on the other side of the piezoelectric portion 13a and has a bonding surface bonded to the base 21.

The piezoelectric portion 13a is configured by stacking a piezoelectric ceramic material into a plurality of layers and includes a voltage terminal 13d to be used for an electric connection to a DC power source, for example. In accordance with a voltage applied to the voltage terminal 13d, the length of the piezoelectric portion 13a in the Z-axis direction perpendicular to the surface of the base member 31 can be changed within a range of 0 to 40 μm with precision of 0.1 μm or less, for example.

One end surface of the anode supporting portion 13 is bonded to the lower surface of the lid body 11b of the reaction tank 11, and the other end surface of the anode supporting portion 13 is bonded to the second surface 21b of the base 21.

The anode supporting portion 13 adjusts the position of the base 21 in the Z-axis direction by adjusting the length of the piezoelectric portion 13a in the Z-axis direction in accordance with application of a voltage. By the adjustment, the anode supporting portion 13 adjusts an inter-electrode distance L2 which is a distance between the electrode surface portion 22 and the surface of the base member 31 in the Z-axis direction.

The cathode portion 14 is constituted by the plate-shaped base member 31. The cathode portion 14 includes a wafer 31a as the base member 31 and a seed layer 31b formed on the wafer 31a. The seed layer 31b can be obtained by forming a laminated film of titanium (Ti) and copper (Cu) on the wafer 31a of silicon (Si) by using a physical depositing method such as a sputtering method or a deposition method. The surface 100 of the seed layer 31b is formed of a copper film. In the embodiment, the base member 31 is circle-shaped and has a diameter of 200 mm. The base member 31 is connected to a cathode of the DC constant current source 16.

The titanium layer is formed to increase adhesion strength for the wafer 31a of silicon and desirably has a film thickness of about 0.1 μm. The copper layer is formed to mainly contribute to energization and desirably has a film thickness of 0.2 μm or more.

As illustrated in FIG. 1, the cathode supporting portion 15 is installed inside the case body 11a. The cathode supporting portion 15 includes a support stand 15a for supporting the base member 31 and a pressing portion 15b for fixing the base member 31 at the support stand 15a.

The plating solution supplying unit 17 includes a plating solution tank 33 which stores the plating solution 36 excluding CO₂ and is connected to the reaction tank 11 through the liquid supplying pipe 34. The liquid supplying pipe 34 is a pipe which forms a flow passage from the plating solution tank 33 up to the inside of the reaction tank 11. In the liquid supplying pipe 34, a control valve 35 for adjusting the flow rate of a fluid flowing inside the pipe is provided.

The plating solution 36 is a fluid including metal ions and an electrolyte, for example. As the plating solution 36, a general copper sulfate plating solution may be used. More specifically, in the embodiment, as the plating solution 36, a general copper sulfate plating solution which is obtained by adding a surfactant to a mixture solution of copper sulfate 5-hydrate and sulfuric acid is used. The plating solution 36 is not limited to the solution, but any other plating solution such as a pyrroline copper sulfate plating solution or a sulfamic acid copper sulfate plating solution may be used.

The supercritical fluid supplying unit 18 includes a carbon dioxide cylinder 37 and a temperature control pump 39 communicating with the carbon dioxide cylinder 37 the reaction tank 11 through the fluid supplying pipe 38.

A supercritical fluid is a fluid of a state which does not belong to any one of a solid, a liquid, and a gas in a state diagram of substance determined based on temperature and pressure. The supercritical fluid is known to contribute to permeability and a high-speed reaction of a nano level, based on properties of high diffusibility, a high density, zero surface tension etc. In the embodiment, as the supercritical fluid, supercritical CO₂ is used. More specifically, in the embodiment, supercritical CO₂ emulsion (SCE) which is emulsified so as to be applied to electroplating by adding a surfactant to carbon dioxide is used.

The carbon dioxide cylinder 37 is a container which stores high-pressure carbon dioxide. The carbon dioxide cylinder 37 stores liquefied CO₂ of 4 N, for example. The temperature control pump 39 is connected to the carbon dioxide cylinder 37 through the fluid supplying pipe 38. The temperature control pump 39 includes a heater 41, a compressor 42 and a pressure gauge 43. The heater 41 heats a carbon dioxide gas supplied from the carbon dioxide cylinder 37. The compressor 42 compresses the carbon dioxide gas. The pressure gauge 43 is connected to an exit side of the compressor 42.

The heater 41 heats carbon dioxide up to a predetermined temperature which is the critical temperature 31.1° C. of carbon dioxide or more, for example, about 40° C. The compressor 42 is a pressurizing device, for example, a high-pressure pump, and pressurizes a carbon dioxide gas up to a predetermined pressure which is the critical pressure 7.38 MPa of carbon dioxide or more, for example, 15 MPa.

In the fluid supplying pipe 38, control valves 44, 45 for adjusting the flow rate of a fluid flowing inside the pipe are provided at respective positions located on an upstream side and a downstream side of the temperature control pump 39.

The supercritical fluid supplying unit 18 supplies carbon dioxide of a flow rate determined by the control valve 44, from the carbon dioxide cylinder 37 to the heater 41. The heater 41 heats the supplied carbon dioxide up to a temperature of 31° that is the critical point, or more. The compressor 42 pressurizes the carbon dioxide up to a pressure of 7.4 MPa that is the critical point, or more, and supplies the carbon dioxide in a supercritical state to the reaction tank 11.

The DC constant current source 16 is a current supplying device to be used for energizing between the anode portion 12 and the cathode portion 14. The DC constant current source 16 reduces metal ions contained inside the plating solution 36 so as to be deposited on the cathode portion 14. The anode of the DC constant current source 16 is connected to the electrode surface portion 22 having a pattern shape through the base 21 of the anode portion 12. A cathode of the DC constant current source 16 is connected to the seed layer 31b of the cathode portion 14.

The treatment container 19 is a container made of metal, for example, and is connected to the reaction tank 11 through the discharge pipe 47. The discharge pipe 47 includes a branch pipe 48 as a branch flow passage which is branched from the middle of the discharge flow passage and is returned to the discharge passage. A control valve 49 which adjusts the flow rate of a fluid flowing inside the pipe is provided at a further upstream side of the discharge pipe 47 from the branched portion. In the branch passage, a back-pressure adjusting valve 51 is provided. The back-pressure adjusting valve 51 is configured by a variable valve which can control the flow rate of the fluid with high precision and has a function for maintaining the pressure of the inside of the reaction tank 11 at 15 MPa which is a predetermined pressure.

An electroplating method which forms a pattern on the base member 31 by using the electroplating apparatus 1 will be described with reference to FIGS. 2 to 6.

In the electroplating method, the electrode surface portion 22, which has a pattern shape as an anode and the base member 31 as a cathode, are separately arranged to oppose each other inside the reaction tank 11. In addition, the plating solution 36 is provided in the reaction tank 11, and the electric potential of the base member 31 is set to be negative. By the setting a plating film 52 of metal is formed on the surface of the base member 31. According to the method, by controlling a distance between the anode and the cathode, a distance between the anode and the surface of the plating film to be formed on the surface of the cathode is set to be smaller than a half value width of a portion of the cross-section of a pattern of a metal plating film having a minimum width.

More specifically, as a pretreatment, the base member 31 is immersed into an electrolytic solution. In the embodiment, by immersing the base member 31 into an aqueous solution of H₂SO₄ of 10 wt. % for one minute, a natural oxide film formed on the surface of the copper film of the seed layer 31b is eliminated. The kind or composition of a pretreatment solution and a treatment time are appropriately adjusted depending on a growth state of such an oxide film, in order to eliminating such an oxide film surely.

The base member 31 and the anode portion 12 which are pretreated are installed to oppose each other inside the reaction tank 11, as illustrated in FIG. 1. After the installation of the base member 31 and the anode portion 12, the lid body 11b of the reaction tank 11 is closed to seal the reaction tank 11.

The control unit 20 illustrated in FIG. 1 adjusts the position of the anode portion 12 in the Z-axis direction by changing the length of the anode supporting portion 13 in the Z-axis direction. More specifically, while the electrode surface portion 22 of the anode portion 12 and the surface of the cathode portion 14 is maintained to be parallel with each other, the control unit 20 sets a distance L2′ at a predetermined value less than 10 μm which is a half value width L1 of a portion of the pattern of the plating film 52 having a minimum width by controlling the inter-electrode distance L2. The distance L2′ is a distance between the anode portion 12 and the surface of the plating film 52 to be formed on the surface of the cathode portion 14, for example.

The condition that the inter-electrode distance L2 is equal to L2′ before electroplating is set based on an electrostatic field simulation, for example. FIG. 3 is a secondary current distribution at the surface of the cathode portion which is obtained by an electrostatic field simulation. FIG. 3 illustrates cases where the inter-electrode distances L2 are respectively 3 μm, 5 μm, and 10 μm for an anode pattern having a width of 10 μm.

As illustrated in FIG. 3, it can be understood that, as the inter-electrode distance L2 decreases, a peak of the current distribution increases and the half value width decreases. Under a condition that the inter-electrode distance L2 is equal to 10 μm, the current distribution is uniform, the ratio between a minimum value and a maximum value of the current is about 0.58, and the half value width for the peak value of the current distribution is 20 μm or more. Thus, even in a case where electroplating is performed in the condition, a plating pattern in which the half value width for the peak value of the thickness of the plating film is 10 μm cannot be obtained. On the other hand, under a condition that the inter-electrode distance L2 is equal to 5 μm, the ratio between the minimum value and the maximum value of the current is decreased to be 0.13. In consideration of an etching-back process after electroplating, the ratio is desirably low and is preferably at least 0.5 or less. The half value width for the peak value of the current distribution of the case is about 10 μm. Thus, in a case where electroplating is performed in the condition, a plating pattern having such a fine width that the half value width for the peak value of the thickness of the plating film is about 10 μm can be obtained. From the viewpoint described above, in the embodiment, the inter-electrode distance L2 before the start of electroplating is set to be less than the half value width L1 of the cross-section of a portion of the metal plating pattern having a minimum width which is formed on the surface of the cathode.

As described above, after the distance L2′ between the anode portion 12 and surface of the plating film 52 to be formed on the surface of the cathode portion 14 is set, the plating solution 36 and CO₂ which is in the supercritical state are introduced into the inside of the reaction tank 11. More specifically, in accordance with an instruction from the control unit 20, the control valve 35 of the liquid supplying pipe 34 is open to give a predetermined flow rate, and the plating solution 36 of the predetermined flow rate is supplied from the plating solution tank 33 to the reaction tank 11.

Subsequently, in accordance with an instruction from the control unit 20, the control valves 44, 45 of the fluid supplying pipe 38 are open to give a predetermined flow rate, and carbon dioxide is supplied from the carbon dioxide cylinder 37 to the temperature control pump 39 through the control valve 44. In accordance with an instruction from the control unit 20, the heater 41 is controlled, and carbon dioxide is heated up to the critical temperature 31.1° C. or higher. In addition, in accordance with an instruction from the control unit 20, the compressor 42 is controlled, and the carbon dioxide gas is pressurized to be at a predetermined pressure, for example, the critical pressure 7.38 MPa or higher. In accordance with an instruction from the control unit 20, the compressor 42 connected to the reaction tank 11 and the back-pressure adjusting valve 51 are controlled, and the inside of the reaction tank 11 is adjusted to 15 MPa. The temperature of the outside of the reaction tank 11 is controlled so as to be 40° C. by an external heater (not shown) provided outside the reaction tank 11.

Each flow rate is set such that the volume ratio between the plating solution 36 and CO₂ which is a supercritical fluid, is 8:2 i.e. CO₂ is 20 vol. %. While, generally, a critical point at which CO₂ is in the supercritical state is 31° C. and 7.4 MPa, in the embodiment, margins are set in the critical temperature of +9° C. and the critical pressure of +7.6 MPa such that all the CO₂ inside the reaction tank 11 is surely in the supercritical state. Such values can be appropriately determined in consideration of the temperature, the pressure, the distribution etc. of the inside of the reaction tank 11.

In accordance with an instruction from the control unit 20, at a time point when the pressure and the temperature of the inside of the reaction tank 11 which are detected by the pressure gauge 43 and a thermometer (respectively not illustrated) become predetermined values or more and stable, the DC constant current source 16 is applied so that a plating current is flown for a predetermined time as a constant current.

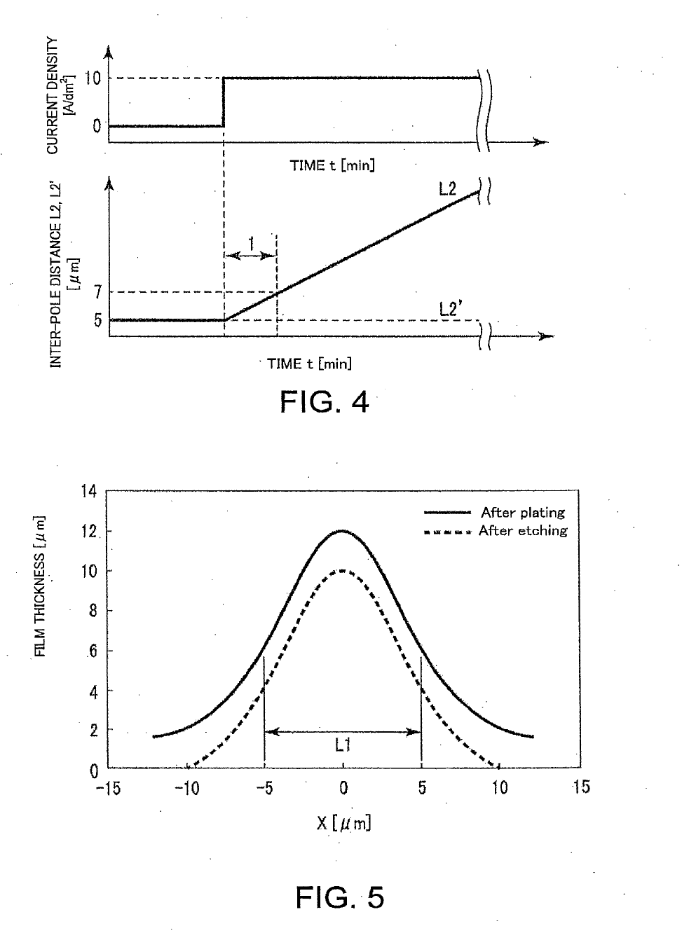

FIG. 4 illustrate graphs representing a relation among a time t [min] , a current density D [A/dm₂], an inter-electrode distance L2 [μm] between the electrode surface portion 22 and the anode portion 12 i.e. the surface of the seed layer 31b in the Z-axis direction, and an inter-electrode distance L2′ [μm] between the electrode surface portion 22 and the surface of the formed plating film 52 in the Z-axis direction.

Inside the reaction tank 11, when the base member 31 becomes a negative electrode according to conduction, the inter-electrode distance L2 is short, and accordingly the electric field of the surface of the base member 31 is concentrated on a portion facing an anode pattern. As a result, on the surface of the base member 31 which is a cathode, a plating film 52 is formed in a pattern shape corresponding to the pattern of the anode so that a copper (Cu) wiring is formed.

The theory of an electrostatic field is directly applied to the electric field which is formed on the surface of the cathode, and the electric field can be obtained by solving a Laplace's differential equation under an appropriate boundary condition. The distribution of a plating current is corrected based on the current density at the time of electroplating and the properties of the plating solution 36. A current distribution obtained from the Laplace's differential equation is generally called as a primary current distribution. In case of electroplating in which a chemical reaction occurs on the surfaces of the electrodes, polarization occurs in the anode and the cathode, and the phenomenon needs to be considered as a boundary condition. As a result, the obtained current distribution is called as a secondary current distribution, and the secondary current distribution tends to be uniformized more than the primary current distribution.

An index of the uniformization of the distribution of the secondary current is determined based on the product W of the conductivity of the plating solution 36 and polarization resistance. In a case where the product W is zero, the distribution of the secondary current is equal to the distribution of the primary current, and, in accordance with an increase in the product W, the distribution of the secondary current is more uniformized than the distribution of the primary current.

Between the distribution of the primary current and the distribution of the secondary current, there is a predetermined relation. For example, in a case where the product W is 0.5, the standard deviation of the distribution of the secondary current is approximately ⅔ of the standard deviation σ of the distribution of the primary current. On the other hand, in a case where the product W is 1.0, the standard deviation of the distribution of the secondary current is approximately ½ of the standard deviation σ.

In general electroplating, in accordance with an increase in the temperature of the plating solution 36, the conductivity of the plating solution 36 tends to increase, and the polarization resistance tends to decrease. A detailed behavior of such a tendency is different based on the plating solution 36 to be used. Thus, in general electroplating which requires a uniform thickness of the plating film, a condition for stabilizing and increasing the product of the conductivity of the plating solution 36 and the polarization resistance as an index is selected. Generally, the electric potential v.s. current characteristic of the surface of the cathode i.e. a negative polarization line has not a linear characteristic but a characteristic close to a secondary curve. Thus, in accordance with an increase in the current density, the polarization resistance tends to decrease. Accordingly, in the general electroplating, it is preferable that the current density is set to be low in a range in which film formation can be performed within an electroplating time allowed in consideration of the productivity. In copper electroplating using a plating solution 36 which is formed of copper sulfate and an sulfuric acid and has a high density of the sulfuric acid called a highly-uniform electrodeposition property bath or a high slow bath, normally, a condition in which the product W is 0.5 or more is mainly used.

In contrast, in the electroplating method according to the embodiment, in order to acquire a pattern-shaped plating film 52 corresponding to the pattern of the electrode surface portion 22 of the anode portion 12, the product W is preferably less than 0.5.

In general copper electroplating, in order to increase the uniformity of the current density on the surface of the base member 31, the current density is set to be 5 A/dm2 or less at which the polarization resistance is large. However, in the embodiment, in order to decrease the polarization resistance, the current density is set to 10 A/dm2 which is higher than the current density of the general copper electroplating. An average film formation speed at the time is about 2 μm/min.

In the embodiment, the control unit 20 performs adjustment for increasing the inter-electrode distance L2 in accordance with the film formation time, the current amount, or the thickness of the plating film 52 to be formed.

FIG. 4 illustrates a relation among the density of a current applied to the cathode and the inter-electrode distances L2 and L2′. By applying a voltage to the voltage terminal 13d in accordance with an elapsed time immediately after the start of electroplating, the control unit 20 controls so as to decrease the length of the piezoelectric portion 13a in the Z-axis direction at a speed which is the same as the average film formation speed of the plating film 52, for example, 2 μm/min. In a case where the inter-electrode distance L2 is short, the distance L2′ between the plating film 52 to be formed on the seed layer 31b and the electrode surface portion 22 which is an anode is decreased depending on the degree of film formation, and the plating film and the electrode surface portion are brought into contact with each other or approaches too much, and a film forming process may be disturbed. However, in the embodiment, by increasing the inter-electrode distance L2 in the Z-axis direction at a speed equal to the film formation speed, the distance L2′ between the surface of the plating film 52 on which a film is formed and the electrode surface portion 22 can be maintained to be a constant value, for example, to be equal to the inter-electrode distance L2 at the time of starting film formation.

After a predetermined time elapses from the start of the electroplating, the DC constant current source 16 stops energization and the control of a Z-axis adjustment mechanism is stopped. For example, a time from the start of the energization to the stop is five minutes.

Subsequently, in accordance with an instruction from the control unit 20, the supercritical fluid and the plating solution 36 provided inside the reaction tank 11 are discharged by opening the control valve 49 provided on a discharge side illustrated in FIG. 1, and the inside of the reaction tank 11 is returned to the normal pressure. In addition, the lid body 11b of the reaction tank 11 is open, and the base member 31 on which a copper film as the plating film 52 is formed is taken out, washed, and dried.

Furthermore, the base member 31 on which the plating film 52 is formed is immersed into a mixture aqueous solution of H₂SO₄ of 10 wt. % and H₂O₂ of 10 wt. %. According to the immersion, etching back for eliminating excess copper deposited among wiring patterns formed by copper electroplating and a copper layer configuring the seed layer 31b is performed.

While copper contained in the plating film 52 is dissolved through the etching-back process, the dissolution thickness is about 2 μm, and accordingly there is no problem in the function of the manufactured semiconductor device 100A. After a Cu residue among the wiring patterns disappears, in order to expose the titanium layer configuring the seed layer 31b, etching of titanium is continued. The etching of titanium is performed using a mixture solution of H₂O₂, ammonia water and an chelating agent. When titanium is melted, most of copper contained in the plating film 52 is not melted.

According to the method described above, a wiring pattern of copper can be formed through copper electroplating on a 150 mm×150 mm area of the surface of the cathode portion 14 which opposes the anode portion 12 of the surface of the cathode portion 14 without using a resist, in order to manufacture the semiconductor device 100A.

For example, by using the electroplating apparatus 1 and the electroplating method described above employing a base member on which a semiconductor device is not formed, as the base member 31, a wiring board can be manufactured by forming a wiring pattern on the base member 31.

FIG. 5 illustrates measurement results of surface shapes of the cooper wiring formed as described above which are obtained by using a laser microscope. FIG. 5 illustrates cross-section profiles after electroplating of the copper wiring and after the etching which are measured by using a laser microscope.

In FIG. 5, the horizontal axis represents a width dimension [μm], and the vertical axis represents a film thickness [μm]. Based on FIG. 5, it can be understood that a wiring having a half value width of about 10 μm for a peak value of 12 μm of the plating film thickness which is similarly to the distribution of the current illustrated in FIG. 3 is formed after electroplating. after etching, a copper wiring having a half value width of about 8 μm for a peak value of about 10 μm of the film thickness, a wiring width of about 20 μm, a wiring height of about 10 μm and an aspect ratio of 0.5 or more is formed.

According to the electroplating apparatus 1 and the electroplating method described above, the anode portion 12 is patterned using the electrode surface portion 22. In addition, by controlling the distance L2 between the anode portion 12 and the cathode portion 14, the distance L2′ between the anode portion 12 and the surface of the plating film to be formed on the surface 100 of the cathode portion 14 is set to be smaller than the half value width L1 of the cross-section of a portion of the pattern of the metal plating film having a minimum width to be formed on the surface 100 of the cathode portion 14. According to such setting, a wiring pattern can be formed with high precision without using a resist. A fine wiring having a high aspect ratio can be formed using a solid material without using a resist. The electroplating method described above indicates an advantage that a semiconductor device having low resistance, superior electrical characteristics, high ductility and a high tensile strength and superior mechanical characteristics can be manufactured, compared with a printing method or an ink jet method using a paste.

According to the electroplating apparatus 1 and the electroplating method described above, by introducing supercritical CO₂ into the reaction tank 11, a pattern of high precision can be formed even in a case where the inter-electrode distance L2 is small. In a case where the inter-electrode distance L2 is short, it is assumed to be difficult to supply ions. However, micelles of supercritical CO₂ contained in the middle of the plating solution 36 having high permeability are provided between the electrodes, and accordingly, the plating solution 36 provided on the periphery of the micelles follows the micelles to flow. As a result, supply of electroplating ions between the electrodes can be promoted.

According to the electroplating apparatus 1 and the electroplating method described above, the inter-electrode distance L2 can be adjusted in accordance with the film thickness of the formed film. Accordingly, also in a case where the inter-electrode distance L2 is short, a gap between the plating film 52 and the anode portion 12 can be secured to be a predetermined value or more. Thus, the electroplating apparatus 1 and the electroplating method can be applied also to forming a plating film 52 having a large film thickness.

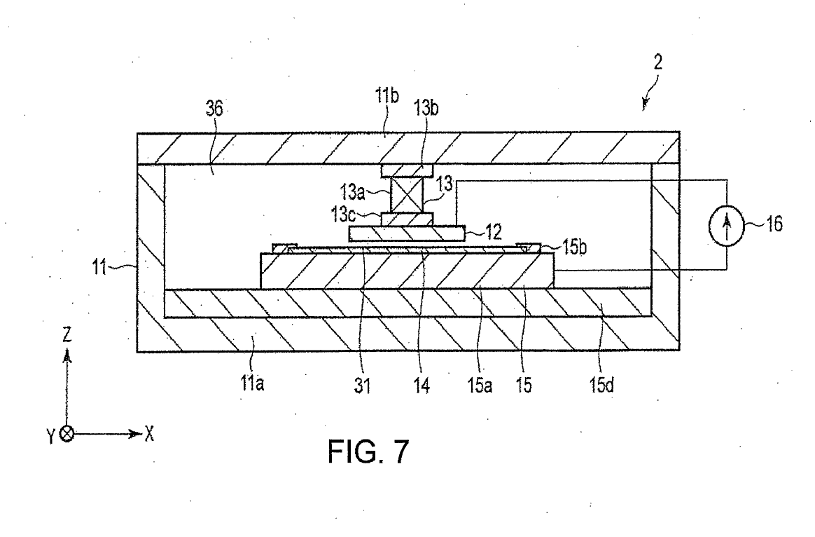

Hereinafter, an electroplating apparatus according to a second embodiment and an electroplating method and a method of manufacturing a wiring board using the apparatus will be described with reference to FIG. 7. As illustrated in FIG. 7, in the electroplating apparatus 2 according to the embodiment and the electroplating method and a method of manufacturing a wiring board or a semiconductor device using the apparatus, an anode portion 12 facing a portion of the cathode portion 14 is used. By alternately repeating movement of the cathode portion 14 or the anode portion 12 along the XY plane and film forming on the cathode portion 14, a pattern of a predetermined plating film is formed on the cathode portion 14. The apparatus and the manufacturing method may be applied to a case where a desired pattern is repeatedly formed on a surface of a seed layer provided on a base member 31 configuring a cathode portion 14.

In the electroplating apparatus 2 according to the embodiment, the shape and the size of the anode portion 12 is configured to be smaller than an area of the base member 31 in which a copper wiring pattern is formed. The film formation is repeatedly performed while relatively moving the anode portion 12 and the cathode portion 14 so that a desired pattern shape is formed parallel at a plurality of positions. The other configuration of the electroplating apparatus 2 and the other process of the electroplating method are similar to the configuration of the electroplating apparatus 1 according to the first embodiment and to the process of the electroplating method using the apparatus.

In the electroplating method according to the embodiment, the anode portion 12 is configured in a pattern shape corresponding to a portion of the cathode portion 14 and is arranged to oppose the cathode portion. As illustrated in FIG. 7, the anode is configured in a size and a pattern shape corresponding to only a portion of the cathode. In the embodiment, the outer shape of the base member 31 is a circular plate shape having a diameter of 200 mm, for example. An area in which a copper wiring pattern is formed is a surface area of the base member 31 which has a square shape of 150 mm×150 mm, for example. The anode portion 12 is a plate of a square shape of 30×30 mm, for example.

A cathode supporting portion 15 of the electroplating apparatus 2 according to the embodiment includes a movement device 15d which can move the support stand 15a along the XY plane under the control of the control unit 20, in addition to a support stand 15a and a pressing portion 15b.

In a state in which the anode portion 12 opposes the cathode portion 14, the electric potential of the cathode portion 14 is set to negative electric potential with respect to the anode portion 12. According to the setting, a pattern of a metal plating film 52 is formed on the surface of the cathode portion 14, By relatively moving the anode portion 12 with respect to the cathode portion 14, the film formation of the pattern of the metal plating film 52 is repeatedly performed for a plurality of times in an alternating manner.

In the electroplating method according to the embodiment, a film forming process in which a pattern-shaped plating film 52 corresponding to the pattern shape of the anode portion 12 is formed on a portion of the surface of the cathode and a movement process in which the cathode and the anode are relatively moved along the XY plane are repeated for a plurality of number of times. By the repeating, a desired pattern shape configured by a plurality of unit patterns which are arranged in parallel with each other is formed on the surface of the cathode.

More specifically, in accordance with an instruction from the control unit 20, similarly to the electroplating apparatus according to the first embodiment and the electroplating method using the apparatus, the base member 31 and the anode portion 12 which are pretreated are arranged to oppose each other with a predetermined distance provided, a plating solution 36 and a supercritical CO₂ are supplied to a reaction tank 11. Subsequently, in accordance with an instruction from the control unit 20, conduction between the electrodes is performed, and a plating film 52 is formed on the base member 31. At the time of forming the film, similarly to the electroplating method using the apparatus according to the first embodiment, the anode supporting portion 13 is controlled so as to separate the electrodes by an inter-electrode distance L2 in accordance with a degree of progress of the film formation, for example, a current amount, an elapsed time or a film thickness.

Similarly to the electroplating method using the apparatus according to the first embodiment, after the process of forming a plating film 52 having a predetermined thickness, the position of the anode portion 12 is shifted by an amount corresponding to the dimension of the anode portion 12 in the X-axis direction or the Y-axis direction, and the inter-electrode distance L2 is returned to an initial value. By causing a current to flow between the electrodes again, a plating film 52 of a pattern corresponding to the pattern of the anode portion 12 is formed on the cathode portion 14. By repeating the film forming process and the movement along the XY plane, the pattern of the plating film 52 is formed over a plurality of number of times in a broad range of the cathode portion 14. For example, a partial film forming process is repeated 25 times corresponding to five rows and five columns while the position is shifted in the X-axis direction or the Y-axis direction by a predetermined pitch, and the process of forming the plating film 52 is performed at 25 positions. According to such a film forming process, copper wiring patterns can be formed in the whole area on the seed layer 31b of the base member 31. Then, similarly to the electroplating method using the apparatus according to the first embodiment, the inside of the reaction tank 11 is returned to the normal pressure, a process of discharging the plating solution 36 is performed, the base member 31 on which the copper film is formed as the plating film 52 is taken out, the base member 31 is washed and dried, and the etching-back process is performed for the base member 31.

According to the apparatus of the embodiment and the electroplating method using the apparatus, advantages which are similar to those of the apparatus according to the first embodiment and the electroplating method using the apparatus are obtained. In the apparatus according to the embodiment and the electroplating method using the apparatus, the anode portion is patterned, and the distance L2 between the anode portion 12 and the cathode portion 14 is controlled. According to such control, the distance L2′ between the anode portion 12 and the surface of the plating film to be formed on the surface of the cathode portion 14 is set to be smaller than the half value width L1 of a portion of the cross-section of the pattern of the metal plating film having a minimum width to be formed on the surface of the cathode portion 14. According to such setting, the wiring pattern can be formed with high precision without using a resist. In addition, according to the apparatus of the second embodiment and the electroplating method using the apparatus, the pattern of the anode portion 12 can be simplified, and the area of the anode portion 12 can be decreased. Accordingly, a time required for designing and manufacturing the anode portion 12 can be decreased.

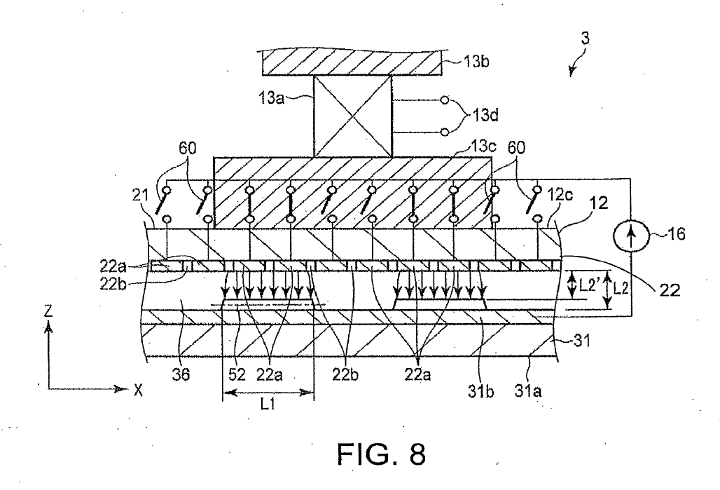

An electroplating apparatus according to a third embodiment, an electroplating method using the apparatus, and a method of manufacturing a wiring board or a semiconductor device will be described with reference to FIGS. 8 to 11. An anode portion 12 includes a plurality of unitary electrode surface portions 22a as fine anode elements, as illustrated also in FIG. 6. Such unitary electrode surface portions 22a are connected to a DC constant current source 16 using a plurality of switches 60 and are configured to be switchable between an on state and an off state. The other configurations of the apparatus according to the embodiment are similar to the configurations of the apparatus according to the second embodiment.

The electrode surface portion 22 is configured by a plurality of unitary electrode surface portions 22a arranged parallel in a matrix pattern of columns and rows spaced by a predetermined gap. The unitary electrode surface portions 22a are connected to the anode of the DC constant current source 16 through a plurality of switches 60 such as MOS transistors which can be electrically turned on and off. Between the plurality of unitary electrode surface portions 22a, an insulating layer 22b is provided, and the unitary electrode surface portions 22a are insulated from each other.

In the embodiment, according to the pattern of a plating film 52 to be formed on the surface of the cathode portion 14, the switches 60 are set such that currents flow through unitary electrode surface portions 22a of a portion corresponding to the pattern. By causing currents to flow only through unitary electrode surface portions 22a connected to the DC constant current source 16, the plurality of unitary electrode surface portions 22a arranged at specific positions serve as anodes.

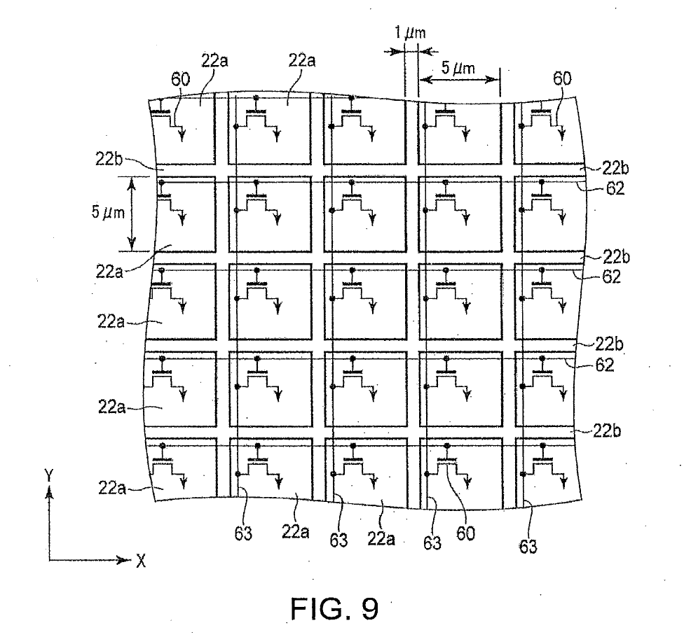

The size of the unitary electrode surface portion 22a which is a fine anode element forming the anode portion 12 is preferably set to be smaller than at least a half value width of the cross-section of a portion of the pattern of the plating film 52 to be formed on the cathode portion 14. For example, a wiring group having a thickness of 10 μm, a half value width of the cross-section of 8 μm, and wirings of a width of 20 μm aligned at an interval of 20 μm with a pitch of 40 μm is formed on the cathode portion 14, as the plating film 52. In such a case, by setting the size of the unitary electrode surface portion 22a to 5 μm and aligning the unitary electrode surface portions 22a at an interval of 1 μm vertically and horizontally, the formation of the plating film 52 can be realized. For example, 5000 unitary electrode surface portions 22a are aligned vertically and horizontally and are arranged on a base 21 which is a plate having a rectangular shape of 30 mm×30 mm. As illustrated in FIG. 9, gate lines 62 and source lines 63 are connected to the unitary electrode surface portions 22a arranged in a plurality of columns and a plurality of rows through switches 60 such as MOS transistors.

The anode of the DC constant current source 16 is connected to the source line 63. The MOS transistors connected to the unitary electrode surface portions 22a to be conducted are selected, and a voltage is applied to the gate lines 62 connected to the selected MOS transistors. By only setting an on and off pattern of each unitary electrode surface portion 22a, the pattern of the plating film 52 to be formed on the cathode portion 14 can be changed without replacing the anode portion 12. By using such transistor switches, for example, a total of 10,000 wirings which includes 5000 wirings of the gate lines 62 and 5000 wirings of the source lines 63 are arranged so that a plurality of unitary electrode surface portions 22a can be switched.

In the electroplating method using the apparatus according to the embodiment, by changing the setting of on and off of the switches 60 connected to the unitary electrode surface portions 22a as fine anode elements of the anode portion 12 so that the pattern of the current flowing through the anode portion 12 is changed, a wiring of a different pattern may be stacked on a copper wiring pattern formed in advance.

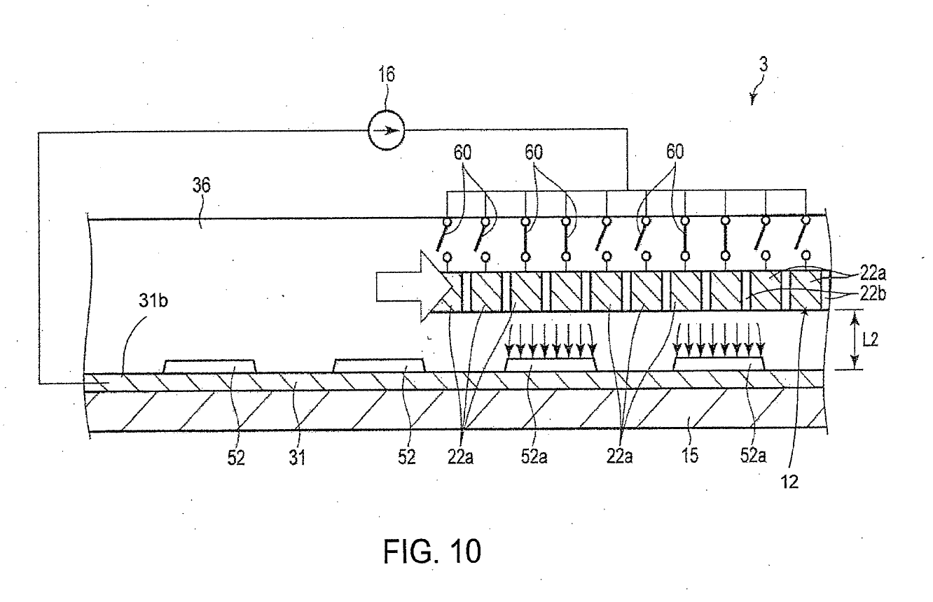

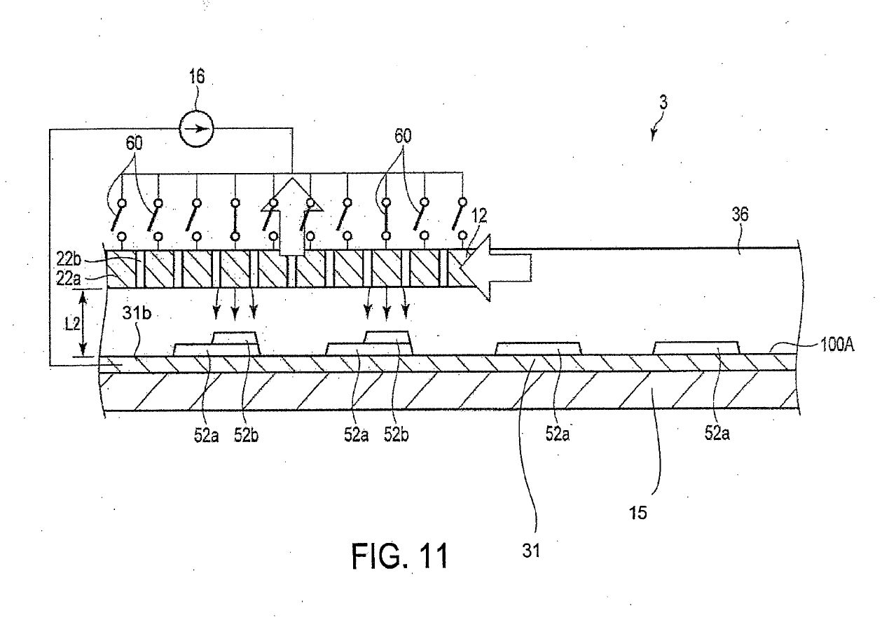

In such a case, as illustrated in FIG. 10, similarly to the electroplating method using the apparatus according to the second embodiment, a plating film 52a which becomes a copper wiring pattern is formed in the whole area on the seed layer provided on the base member 31. After the plating film 52a is formed, as illustrated in FIG. 11, the base member 31 is returned to the initial position in the X-Y directions, and the anode portion 12 is raised by a height of the copper wiring of the formed plating film 52a, in order to set an inter-electrode distance L2. In addition, an electroplating process which includes changing the on and off setting of the switches 60 to obtain a different current pattern and forming a plating film 52b having a predetermined shape is performed. According to such a method, the pattern to be formed in each electroplating process can be set by switching the switches 60, and thus the plating films 52a, 52b to be formed in respective electroplating processes can have mutually-different patterns. Similarly, plating films having mutually-different pattern shapes can be stacked by a plurality of film forming processes.

As a result, on the base member 31, not only a copper wiring having a constant thickness but also a copper structure having a complex three-dimensional shape such as a pattern including copper posts having a pillar shape on a copper wiring can be formed.

According to the electroplating apparatus 3 of the embodiment, the electroplating method using the apparatus and the method of manufacturing a wiring board or a semiconductor device, advantages similar to those of the apparatuses according to the first and second embodiments, the electroplating methods using the apparatuses, and the method of manufacturing the wiring board or the semiconductor device are obtained. More specifically, since a fine pattern shape can be realized without using a resist, the versatility is high, and the manufacturing process can be performed at low cost. In addition, the obtained wiring has low resistance, superior electrical characteristics, high ductility and a high tensile strength, and superior mechanical characteristics.

According to the electroplating apparatus 3 of the embodiment, the electroplating method using the apparatus and the method of manufacturing a wiring board or a semiconductor device, an arbitrary pattern of the plating film can be set by switching the plurality of unitary electrode surface portions 22a having an array shape configuring the anode portion 12 by using the switches 60. Accordingly, the versatility is high, and various pattern shapes can be manufactured at a high speed. Particularly, since the anode portion does not need to be prepared according the wiring pattern of a product, a time required for manufacturing the anode portion can be decreased, and work or time for replacing the anode portion etc. can be reduced, Accordingly, a plurality of products can be consecutively treated.

According to the electroplating apparatus 3 of the embodiment, the electroplating method using the apparatus and the method of manufacturing a wiring board or a semiconductor device, in a case where film formation is repeated for stacking, a different pattern shape can be easily formed, and a complex three-dimensional structure can be consecutively formed. Accordingly, copper posts on a rewiring which are used in a case where the reliability of a connection with an WCSP substrate is to be enhanced, copper posts which are used at the time of performing a solder connection of a fine pitch, etc. can be formed continuously after the formation of the rewiring. In addition, the electroplating apparatus 3 of the embodiment, the electroplating method using the apparatus, and the method of manufacturing a wiring board or a semiconductor device can be applied to a complex three-dimensional structure which is used in an MEMS etc.

In a case where the number of the unitary electrode surface portions 22a of the anode portion is enormous, it is difficult to extract wirings from a plurality of the unitary electrode surface portions 22a by using a general switch. However, according to the embodiment, by employing the transistor switches connected to the rows and columns, switching can be performed using the switches, and thus a fine pattern shape of the plating film can be realized.

According to the electroplating apparatus 3 of the embodiment, the electroplating method using the apparatus and the method of manufacturing a wiring board or a semiconductor device, the distance L2′ between the anode portion 12 and the surface of the plating film to be formed on the surface of the cathode portion 14 is set to be smaller than the half value width L1 of the cross-section of a portion of the pattern of the metal plating film having a minimum width to be formed on the surface of the cathode portion 14. While, in the embodiment, a distance up to a film formation surface is maintained by separating the anode portion 12 from the cathode portion 14 in accordance with a degree of the film formation, the distance is not limited to being maintained in that manner.

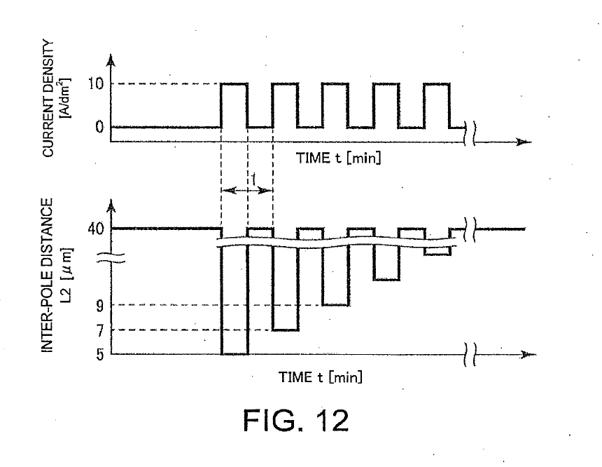

For example, as an electroplating method according to another embodiment, as illustrated in FIG. 12, supplying ions between the electrodes may be continuously promoted by stopping the film forming process and temporarily increasing the inter-electrode distance L2.

In the electroplating method according to the embodiment, in a state in which the distance L2′ between the anode portion 12 and the surface of a plating film to be formed on the surface of the cathode portion 14 is smaller than the half value width L1 of the cross-section of a portion of the pattern of the metal plating film having a minimum width to be formed on the surface of the cathode portion, the plating film is formed by setting the electric potential of the cathode portion to negative electric potential with respect to the anode portion. In addition, forming the plating film is stopped, and the distance L2′ is increased to be more than the half value width L1 of the cross-section of a portion of the pattern of the metal plating film having a minimum width to be formed on the surface of the cathode portion 14. Such processes are alternately performed. At the time of forming the film, the distance L2′ between the anode portion 12 and the surface of the plating film to be formed on the surface of the cathode portion 14 is smaller than a half value width L1 of a cross-section of a portion of the pattern of the metal plating film having a minimum width, and the distance is short, for example, below 10 μm, and thus it becomes difficult to supply ions. For the reason, in order to promote the supply of ions supplied between the electrodes, the inter-electrode distances L2 and L2′ are temporarily increased. For example, in a case where the inter-electrode distance L2 before electroplating is set to 5 μm, the conduction is stopped every other predetermined time, and the inter-electrode distance L2 is increased up to a predetermined value or more during the stop of the conduction. For example, the inter-electrode distance L2 is increased up to about 40 μm.

The application of a current is intermittently performed. In addition, the distance between the anode portion 12 and the cathode portion 14 is temporarily increased during a period in which the current is not applied, and the distance between the anode portion 12 and the cathode portion 14 is decreased during a period in which the current is applied. More specifically, as illustrated in FIG. 12, a voltage applied to the voltage terminal 13d of the anode supporting portion 13 which is an adjustment device adjusting the inter-electrode distance L2 is set to a pulse shape, and the position in the Z-axis direction is set to be changed in a stepped manner.

According to the electroplating method described above, in the state in which the inter-electrode distance L2 is increased, the supply of ions is promoted. In addition, for example, in a case where the inter-electrode distance L2 is increased to 40 μm after being decreased to 5 μm, the volume between the electrodes is temporarily compressed to ⅙, and subsequently is expanded by six times. For the reason, an increase and a decrease in the pressure occurs, and the plating solution 36 provided on the periphery is forced to flow in or be discharged from between the electrodes, and the supply of ions according to the flow of the plating solution 36 is markedly promoted. Since there is a period in which the inter-electrode distance L2 is increased, the plating solution 36 present between the anode portion 12 and the cathode portion 14 can be easily caused to flow, and the speed of supply of copper ions is increased. As a result, the electroplating process can be performed at a higher current density

In the electroplating apparatuses, the electroplating methods using the apparatuses and the methods of manufacturing a wiring board or a semiconductor device as described above, the pattern of the electrode surface portion 22 which becomes an anode is formed to have a minimum width of the pattern width as 10 μm at an interval of 30 μm with a pitch of 40 μm, the configuration of the pattern is not limited to such a configuration. Since the shape of the plating film 52 which is formed on the cathode portion 14 changes according to the current density, the properties of the plating solution etc. in order to acquire a plating pattern desired to be formed, the design of the anode pattern may be changed. For example, in a case where the plating solution is changed, the anode portion 12 may be changed to have a width of the pattern of 8 μm and an interval of 32 μm.

The plating solution 36 and the supercritical fluid are not limited to the materials described above, but any other plating solution 36 including nickel etc. or a supercritical fluid such as H₂O may be used. In addition, in a case where a plating solution provided in a narrow area between the cathode portion 14 and the anode portion 12 can flow by using the plurality of the electroplating methods described above, the supercritical fluid does not necessarily need to be mixed into the plating solution. While the laminated film of titanium (Ti)/platinum (Pt) composing the electrode surface portion 22 as an anode becomes a so-called insoluble anode, a soluble anode of iridium (Ir), pure copper, copper containing phosphor (P) etc. can be also used instead of platinum (Pt).

In the plurality of the electroplating apparatuses described above, as the anode supporting portion 13 adjusting the position in the Z-axis direction, the piezo-type adjustment device including a piezoelectric element was described as an example. However, the anode supporting portion is not limited thereto, but for example, a mechanism of a mechanical type using a rotation motor and a gear or various mechanisms such as a voice coil type or a linear motor type may be used. In addition, in the plurality of the electroplating apparatuses illustrated in FIGS. 7 and 8, the configuration moving the anode portion 12 are used, but the configuration is not limited the above configuration. For example, a configuration for moving the cathode portion 14 may be employed, or a configuration moving both the anode portion 12 and the cathode portion 14 may be applied as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electroplating method comprising:
arranging an anode portion having a pattern and a cathode portion in a reaction tank so as to opposite to each other with a distance provided;
providing a plating solution containing at least metal ions for electroplating, an electrolyte and a surfactant in the reaction tank; and
forming a pattern of a metal plating film on a surface of the cathode portion by setting the cathode portion at a negative electric potential with respect to an electric potential of the anode portion,
wherein a distance between the anode portion and a surface of a pattern of the metal plating film to be formed on the surface of the cathode portion is set to be smaller than a half value width of a cross-section of a portion of the pattern of the metal plating film having a minimum width by controlling a distance between the anode portion and the cathode portion.

2. The method according to claim 1, wherein the inside of the reaction tank is pressurized to have an atmospheric pressure or higher.

3. The method according to claim 1, wherein a supercritical fluid is provided in the reaction tank.

4. The method according to claim 1, wherein the distance between the anode portion and the cathode portion is increased according to at least one of a time period of forming the metal plating film, a current amount to be applied to the anode portion or the cathode portion, and a thickness of the metal plating film to be formed.

5. The method according to claim 4, wherein the method includes alternately performing forming the metal plating film by setting the electric potential of the cathode portion at a negative electric potential with respect to that of the anode portion, in a state in which the distance between the anode portion and the surface of the pattern of the metal plating film to be formed on the surface of the cathode portion is smaller than the half value width of the cross-section of the portion of the pattern of the metal plating film having a minimum width, and
stopping forming the metal plating film and increasing the distance between the anode portion and the surface of the pattern of the metal plating film to be formed on the surface of the cathode portion so as to be larger than the half value width of the cross-section of the portion of the pattern of the metal plating film having a minimum width.

6. The method according to claim 1, wherein a pattern which opposes a portion of the cathode portion is formed on the anode portion, and the method includes alternately repeating for a plurality of times to form the metal plating film in a pattern shape on the surface of the cathode portion by setting the electric potential of the cathode portion at a negative electric potential with respect to that of the anode portion in a state in which the anode portion opposes the cathode portion, and relatively moving the anode portion with respect to the cathode portion.

7. The method according to claim 1, wherein the anode portion includes a plurality of anode elements arranged in an array and the anode elements are connected to a power source through a plurality of switches respectively, and wherein a metal plating film having a pattern shape corresponding to a current application pattern which is applied to the anode portion and is formed according to an on or off state of each of the switches is produced.

8. The method according to claim 7, wherein the pattern shape of the anode portion is switched by switching on or off at least one of the plurality of switches.

9. An electroplating apparatus comprising:
a reaction tank configured to house a plating solution;
an anode portion provided inside the reaction tank and has a pattern;
a cathode portion provided inside the reaction tank and arranged to oppose the anode portion, the cathode portion being set such that a distance between the anode portion and a surface of a metal plating film to be formed on a surface of the cathode portion is smaller than a half value width of a cross-section of a portion of a pattern of the metal plating film having a minimum width; and
a power source to be connected to the anode portion and the cathode portion.

10. The apparatus according to claim 9, further comprising:
an adjustment device configured to adjust the distance between the anode portion and the cathode portion by moving at least one of the anode portion and the cathode portion;
a plating solution supplying unit which provides the plating solution into the reaction tank; and
a control unit which controls operations of the power source, the adjustment device and the plating solution supplying unit and forms a pattern of the metal plating film on the surface of the cathode portion by setting an electric potential of the cathode portion at a negative electric potential with respect to that of the anode portion in a state in which the anode portion and the cathode portion are set in the reaction tank where the plating solution is provided such that a distance between the anode portion and a surface of the metal plating film to be formed on the surface of the cathode portion is smaller than a half value width of a cross-section of a portion of the pattern of the metal plating film having a minimum width.

11. The apparatus according to claim 9, further comprising a supercritical fluid supplying unit which supplies a supercritical fluid into the reaction tank, wherein the plating solution to be supplied from the plating solution supplying unit contains at least metal ions for electroplating, an electrolyte and a surfactant, and the control unit controls operation of the supercritical fluid supplying unit.

12. The apparatus according to claim 9, wherein the anode portion includes a conductive base, an electrode surface portion formed in a pattern shape on the base, and an insulating film formed on the base and at an area adjacent to the electrode surface portion, the cathode includes a base member and a seed layer formed on the base member, the base is connected to a positive-electrode side of the power source, and the base member is connected to a negative-electrode side of the power supply.

13. The apparatus according to claim 10, wherein the control unit increases the distance between the anode portion and the cathode portion according to at least one of a time period of forming the metal plating film, a current amount to be applied to the anode portion or the cathode portion, and a thickness of the metal plating film to be formed.

14. The apparatus according to claim 10, wherein the control unit performs control to alternately repeat:
forming the metal plating film by setting the distance between the anode portion and the surface of the metal plating film to be formed on the surface of the cathode portion to be smaller than the half value width of the cross-section of a portion of the pattern of the metal plating film having a minimum width and setting the electric potential of the cathode portion at a negative electric potential with respect to that of the anode portion; and
stopping forming the metal plating film and increasing the distance such that the distance between the anode portion and the surface of the pattern of the metal plating film to be formed on the surface of the cathode portion is larger than the half value width of the cross-section of a portion of the pattern of the metal plating film having a minimum width.

15. The apparatus according to claim 10 wherein the anode portion includes a pattern and is arranged to oppose a portion of the cathode portion, and the control unit alternately repeats for a plurality of times forming a pattern of the metal plating film on the surface of the cathode portion by setting the electric potential of the cathode portion at a negative electric potential with respect to that of the anode portion in a state in which the anode portion opposes the cathode portion and moving the anode portion relatively with respect to the cathode portion.

16. The apparatus according to claim 9, wherein the anode portion includes a plurality of anode elements arranged in an array, a plurality of switches which can switch connecting states are connected between the anode elements and the power source respectively, and the control unit changes the shape of the pattern of the anode portion by switching at least one of the switches.

17. The apparatus according to claim 9, wherein the anode portion includes a plurality of anode elements arranged in an array, a plurality of switches which can switch connecting states of the anode elements are connected to the anode elements respectively, and the control unit controls the shape of the metal plating film by switching at least one of the switches.

18. The apparatus according to claim 17, wherein the switches are transistor switches respectively connected to columns and rows of the anode elements.

19. The apparatus according to claim 9, further comprising a pressurization device which pressurizes the inside of the reaction tank to atmospheric pressure or higher.

20. A method of manufacturing a semiconductor device, comprising:
Arranging an anode portion having a pattern and a cathode portion so as to oppose to each other in a reaction tank, and setting a distance between the anode portion and a surface of a metal plating film to be formed on a surface of the cathode portion to be smaller than a half value width of a cross-section of a portion of a pattern of the metal plating film having a minimum width;
providing a plating solution at least containing metal ions for electroplating, an electrolyte and a surfactant in the reaction tank; and
forming a pattern of a metal plating film on the surface of the cathode portion by setting an electric potential of the cathode portion to a negative electric potential with respect to that of the anode portion.
